(19) United States
(12) Patent Application Publication
(10) Pub. No.: US 2014/0154894 A1
(43) Pub. Date: Jun. 5, 2014

(54) Method and Device for Producing an Electric Contact Sensor Plate

(71) Applicant: Andreas Heise, Erzhausen (DE)

(72) Inventor: Andreas Heise, Erzhausen (DE)

(21) Appl. No.: 14/007,127

(22) PCT Filed: Mar. 23, 2012
(86) PCT No.: PCT/EP2012/055162

§ 371 Date: Dec. 20, 2013

(30) Foreign Application Priority Data
Mar. 24, 2011 (DE) 10 2011 006 070.7

(51) Int. Cl. H05K 3/20; H05K 13/04; H05K 1/11

(52) U.S. Cl. CPC H05K 3/20; H05K 1/118; H05K 13/04
USPC 439/67; 29/874; 29/842; 29/739

(57) ABSTRACT

A method for producing an electric contact sensor plate and for populating an electric or electronic module with the contact sensor plate in an automated manner is provided. An end piece of a metal foil strip is fed in a feeding step, in which the contact sensor plate is positioned on the electric or electronic module in a positioning step, and in which the contact sensor plate is fastened on the electric or electronic module in a fastening step. The method is characterized in that the contact sensor plate is produced by being severed from the foil strip in a severing step that follows the feeding step and precedes the positioning step.

### CROSS REFERENCE TO RELATED APPLICATIONS

This application claims priority to German Patent Application No. 10 2011 006 070.7, filed Mar. 24, 2011, and PCT/EP2012/055162, filed Mar. 23, 2012.

### FIELD OF THE INVENTION

The invention relates to a method for producing an electric contact sensor plate and for populating an electric or electronic module with the contact sensor plate in an automated manner to a populating device for producing an electric contact sensor plate and for populating an electric or electronic module with the contact sensor plate in an automated manner, and to a contact sensor plate, and to the use thereof.

### BACKGROUND OF THE INVENTION

For efficient and automated production of complex electronic devices, the individual electronic components, which together form the device, are normally first combined to form individual modules. These modules, for example, are individual printed circuit boards, which are populated on one side or also on both sides with components before the printed circuit boards are electrically interconnected to complete the device. The electric connections of the individual printed circuit boards or modules are often formed as a plug connection or as a spring contact connection, since the production of solder connections between the individual printed circuit boards is associated with a comparatively high level of effort. In particular, spring contact connections are found here in a large number of electronic devices produced in an automated manner, since they have the advantage compared to plug connections of better compensating for any inaccuracies encountered when joining together the modules.

In this regard, DE 102 44 760 A1 discloses a pressure sensor assembly consisting of a pressure sensor casing, in which a piezoelectric measuring element is arranged on the surface of a measuring element carrier. The measuring element has sensor electronics located outside the pressure sensor casing in a governor casing. In order to produce an electric connection between the governor casing and the pressure sensor casing, thin-sheet strips produced by means of a punching method are embedded as contact points in a contact carrier of the pressure sensor casing, said contact points being contacted by a rod-shaped spring contact from the governor casing.

A method for leak identification in a casing of an electronic control device is described in DE 10 2007 057 694 B4. The method comprises applying pressure to the casing and subsequently evaluating the deformation of the casing caused by the pressure. Here, the deformation is a measure for the tightness of the casing and is detected via one or more spring contacts integrated into the casing, which close or separate an electric circuit depending on the deformation or application of pressure.

A capacitive pressure sensor for a motor vehicle braking system is known from DE 10 2005 015 160 A1 and is formed by the connection of metal surfaces of a control device and a hydraulic unit. The metal surfaces constitute a capacitor, of which the capacitance is changed in the event of a pressure-induced deformation. This change to the capacitance is in turn a measure for the application of pressure to the metal surface. The electric contactings of the metal surfaces forming the capacitor and also a reference capacitor are produced here inter alia via spring contacts.

Because, due to design, spring contact connections cannot have the same level of robustness of a solder connection, it is necessary when producing electric connections of this type to take special care with respect to the electric contacting, which must always remain reliable under all operating conditions. This is achieved in accordance with the prior art by treating the contact surfaces by means of suitable metals, such as gold, silver or copper. Because, however, the production of all conductive tracks and contact points of a printed circuit board from the aforementioned metals is too expensive and the use of different metals for conductive tracks and contact points is also associated with disproportionately high effort, the contact points according to the prior art are soldered onto the printed circuit board in the form of contact sensor plates during the population of the printed circuit board, for example as SMD components. These contact sensor plates are normally punched out from sheet metal plates or sheet metal strips and are treated on both sides in spite of the high material costs, since an alignment of the individual contact sensor plates is too complex and an incorrect population of the printed circuit board leads to a reduced process yield and therefore to higher effective production costs.

The object of the invention is therefore to propose a method which enables simple and efficient population of a printed circuit board with contact sensor plates treated on just one side.

### SUMMARY AND INTRODUCTORY DESCRIPTION OF THE INVENTION

This object is achieved in accordance with the invention by the method for producing an electric contact sensor plate and for populating an electric or electronic module with the contact sensor plate in an automated manner.

The invention relates to a method for producing an electric contact sensor plate and for populating an electric or electronic module with the contact sensor plate in an automated manner, in which an end piece of a metal foil strip is fed in a feeding step, in which the contact sensor plate is positioned on the electric or electronic module in a positioning step, and in which the contact sensor plate is fastened on the electric or electronic module in a fastening step. The method is characterized in that the contact sensor plate is produced by being severed from the foil strip in a severing step that follows the feeding step and precedes the positioning step. Since the contact sensor plates produced by the method according to the invention are produced directly during the population process, the advantage that the contact sensor plates do not have to be sorted in magazines or belts before the actual population process is firstly provided whereby the population effort is reduced. This constitutes a significant simplification of population processes known per se. Since, in the feeding step, an end piece of a foil strip is additionally fed, from which the contact sensor plates are severed in the severing step, the alignment of the contact sensor plates can also be checked in a simple manner via the alignment of the foil strip, which enables treatment of the contact sensor plates on just one side with material of a higher quality. A complex alignment of the individual contact sensor plates is therefore no longer necessary. Rather, it is thus sufficient to feed the foil strip already with the desired alignment. Since the alignment of the contact sensor plates corresponds to the alignment of the foil strip from which they are severed and a multiplicity of contact sensor plates are severed from the foil strip, the one-time alignment of the foil strip enables the simultaneous alignment of the multiplicity of contact sensor plates. This constitutes a simplification and increase in efficiency of population processes known per se.

The contact sensor plates are each severed from the end piece of the foil strip such that the foil strip is shortened by each sever by the length of a contact sensor plate. It is also possible and preferable however within the meaning of the invention for a contact sensor plate not to be severed from the foil strip in the strictly literal sense of the term “sever,” but for the contact sensor plate to be removed from the end piece of the foil strip, for example by means of punching. This would enable, for example, the production of round contact sensor plates from a rectangular foil strip. In this case, the term “end piece” within the meaning of the invention does not necessarily denote the actual end of the foil strip, but merely the end piece of the part of the foil strip from which a contact sensor plate has not yet been removed. If the contact sensor plate has not been severed from the foil strip in the strictly literal sense, but instead has been removed therefrom, the part of the foil strip from which the contact sensor plate was removed can additionally be severed, such that the end piece again constitutes the actual end of the foil strip. Alternatively, the part of the foil strip from which the contact sensor plate has been removed can also be wound onto a roll, for example.

It is likewise possible within the meaning of the invention for not only an individual contact sensor plate to be produced and positioned and fastened in each of the mentioned steps, but for two or more contact sensor plates to be produced and positioned and fastened at the same time in each case. It is equally possible and preferable within the meaning of the invention to sever and position strip portions which are likewise used to conduct current.

The foil strip is preferably fed with a predefinable step width. Due to the possibility to predefine the step width in the feeding step, the advantage is provided that one or more contact sensor plates can be severed from the foil strip or removed from the foil strip at the same time depending on requirements. Contact sensor plates of different sizes can also be produced in alternating sequence by adapting the step width to the size of the contact sensor plates required next. Here, the step width can be predefined for example by means of markings on the foil strip, which are identified by the method according to the invention.

Within the meaning of the invention, the term “step width” does not exclusively denote the feeding in individual steps, which are each separated from one another by a standstill of the foil strip, but also a continuous feed at different speeds. In the latter case, a large step width is implemented by a predominantly comparatively faster feed, since a faster feed leads to a comparatively larger fed part of the foil strip in the same time period. Conversely a small step width can be implemented by a predominantly comparatively slower feed.

In the meaning of the invention, the term “contact sensor plate” is not to be understood to mean exclusively substantially two-dimensional plates with approximately identical extensions in the two extension dimensions, such as circles, ovals and squares, but also strip-like plates, of which the extension in one dimension exceeds the extension in the other dimension a number of times over.

In addition, it is advantageous for the foil strip to be stored wound into a roll or wound onto a roll, wherein the roll is unwound in the feeding step. The feeding of a comparatively long foil strip is thus enabled in a simple manner. The longer the foil strip, the less often must the method be interrupted in order to provide a new foil strip. Due to the winding into a roll or onto a roll, the foil strip is additionally available stored in a comparatively compact manner.

It is furthermore advantageous for the foil strip to be severed from a metal foil, wherein at least a first side of the foil is coated with a noble-metal coating. The severing from a foil enables the production of the foil strip in a simple manner. Since the foil is coated beforehand on one side with a noble metal, there is the further advantage that each foil strip does not need to be coated individually. This simplifies the production of the coated foil strip significantly and contributes even in advance to the simplification of the method according to the invention compared to generic methods known per se.

In a further preferred embodiment, the foil is provided with shaped recesses, which form a geometry of the foil strip and/or of the contact sensor plate and/or of the step width of the feeding step. This provides the advantage that a specific shaping of the contact sensor plate can be predefined, at least in portions, already before the production method and the population method. For example, the production of non-rectangular geometries of the contact sensor plate is thus possible by means of a simple severing step, without the need for a specific “removal”. In addition, the shaped recesses can be used in a simple manner as markings in order to predefine the step width during the feeding step.

In particular, it is preferable for the noble-metal coating to consist of gold or silver or nickel or copper or of an alloy containing at least one of these metals. These metals or alloys have comparatively good properties as electric conductors and thus enable a coating of high electrical quality.

Furthermore, it is particularly preferable for a second side of the foil to be coated additionally or alternatively with a coating formed of solder. Since the second side of the metal foil is coated with solder, the contact sensor plate can be soldered and therefore fastened on the electric or electronic module in the fastening step simply by being heated. In addition, not each contact sensor plate has to be coated individually with solder, which in turn contributes to the simplification of the method according to the invention compared to the methods known from the prior art. In addition it is possible to position and then solder the contact sensor plates in a solder paste imprinted onto the electric or electronic module.

Within the meaning of the invention, the term “solder” is to be understood to mean any soldering agent suitable for a soldering process, such as tin or similar alloys known per se.

A width of the contact sensor plate is preferably defined by a width of the foil strip, and a length of the contact sensor plate is preferably defined in the severing step. The dimensions of the contact sensor plate can thus be defined in a simple manner. The width of the contact sensor plate is defined here before the population process by the selection of the width of the foil strip, whereas the length of the contact sensor plate is defined directly during the population process via the step width of the feeding step and can be predefined as required.

In addition, it is advantageous for the contact sensor plate to be produced substantially in a disk-shaped manner. The disk-shaped geometry can be removed here from the end piece of the foil strip either in the severing step, or a foil strip can already be fed that is provided with shaped recesses which allow a simple severing of pre-formed, substantially disk-shaped contact sensor plates.

In a further preferred embodiment, the electric or electronic module is a printed circuit board of an electronic control unit of a vehicle braking system. Since control units of this type generally consist of a plurality of printed circuit boards, which have to be joined to one another via electric connections, the method according to the invention can be used here advantageously and contributes to the simplification and increase in efficiency of the production process of the control unit.

The present invention also relates to a populating device for producing an electric contact sensor plate and for populating an electric or electronic module with the contact sensor plate in an automated manner, comprising feeding means and positioning means and fastening means. The feeding means feeds an end piece of a metal foil strip, the positioning means positions the contact sensor plate on the electric or electronic module, and the fastening means fastens the contact sensor plate on the electric or electronic module. The populating device is characterized in that it additionally comprises severing means, which severs the contact sensor plate from the foil strip, wherein the feeding means feeds the end piece of the foil strip to the severing means for severing, and in that the populating device carries out the method according to the invention. Since the populating device according to the invention thus comprises all means necessary for carrying out the method according to the invention and carries out said method, the advantages already described are produced.

The populating device is preferably formed as an SMD populating device and populates the electric or electronic module with SMD elements. SMD populating devices offer the advantage, due to the small size of the SMD components, that a tight and compact population of the surface of an electric or an electronic module is enabled. The contact sensor plates are in this case likewise produced in the size of the SMD components and, similarly thereto, are fastened on the electric or electronic module.

It is furthermore preferable for the feeding means to feed the end piece of the foil strip by means of unwinding from a roll, and for the positioning means to pick up the contact sensor plate by means of suction and to position it on the electric or electronic module by means of a coordinated movement and to deposit it by terminating the suction, and for the fastening means to solder the contact sensor plate onto the electric or electronic module by means of heating or to adhesively bond the contact sensor plate onto the electric or electronic module by means of conductive adhesive bonding. The described means are suitable for enabling the populating device according to the invention to carry out the method according to the invention in a manner that is as easy at it is effective.

In addition, it is advantageous for the severing means to sever the contact sensor plate from the foil strip by means of cutting or punching. Both a cutting process and a punching process are suitable for severing, removing or detaching the metal foil strip. Since these processes are additionally to be implemented and performed in a simple manner, they contribute to the simplicity, robustness and effectiveness of the populating device according to the invention.

In addition, the populating device additionally populates the electric or electronic module with further elements. Due to the simultaneous population of the electric or electronic module with the contact sensor plates according to the invention and further components, the overall population process remains compact and cost-efficient, since there is no need for a separate populating device that produces the contact sensor plate and fastens it on the electric or electronic module in a separate method.

The present invention further relates to a contact sensor plate which consists of gold or silver or nickel or copper or of an alloy containing at least one of these metals and in particular is produced by means of a populating device according to the invention. The contact sensor plate is characterized in that it is substantially two-dimensional and an extension in a third dimension is no greater than about 3 mm and in particular no greater than about 1.5 mm. Due to the short extension of the contact sensor plate in the third dimension, that is to say due to the low height of the contact sensor plate, the advantage is provided that the contact sensor plate is comparatively light compared to generic contact sensor plates and has only comparatively low material requirements, which in turn keeps the production costs low. A further advantage is that a comparatively large number of contact sensor plates according to the invention can be blister-packed in a space-saving manner.

The invention further relates to a use of the contact sensor plate as a contact point connector between at least two electric contact points. In particular, a strip-shaped contact sensor plate can thus be used to electrically interconnect two or more contact points on the same printed circuit board. In this case, a conductive track located on the printed circuit board can also be bridged, for example. It is also possible and preferable to interconnect two or more contact points on different printed circuit boards.

### BRIEF DESCRIPTION OF THE DRAWINGS

Exemplary embodiments will emerge from the following detailed description provided with reference to the figures, in which:

FIG. 1 shows a flow diagram which illustrates the individual process steps of a possible embodiment of the method according to the invention,

FIG. 2 shows a schematic view of a possible design of the device according to the invention, and

FIG. 3 shows a metal foil from which a metal foil strip is severed, and also foil strips having different shaped recesses.

### DETAILED DESCRIPTION OF THE INVENTION

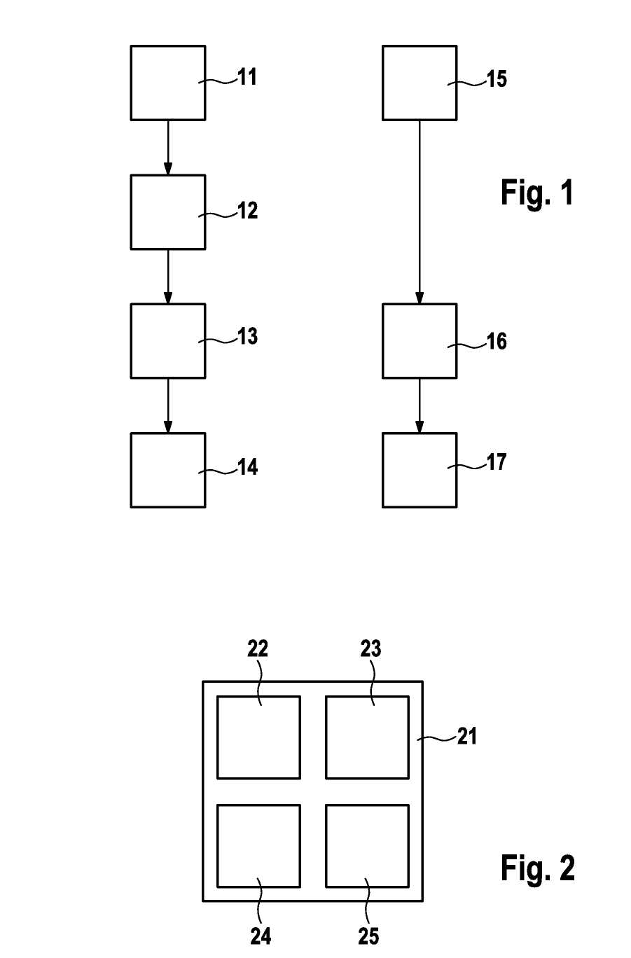

FIG. 1 shows an exemplary and schematic sequence of the method according to the invention in the form of a flow diagram. In step 11, an end piece of a metal foil strip is first fed within the populating device to the severing means in an automated manner. The foil strip is a sheet metal foil, of which the upper face has been provided with a gold coating by means of vapor deposition, whereas the lower face has been coated galvanically with a tin alloy. In a method analogous to step 11, an SMD resistor is removed in method step 15 from a magazine strip provided for this purpose, which is formed in accordance with the example as what is known as a blister. This step is also performed in an automated manner and by means of the same populating device. In method step 12, the end piece of the foil strip is severed in a cutting process. The foil piece severed in such a way constitutes a contact sensor plate. In the following step 13, the contact sensor plate is suctioned by means of a vacuum suction apparatus and is positioned on the printed circuit board to be populated. The contact sensor plate is deposited on the printed circuit board by switching off the vacuum generation in an automated manner, and the contact sensor plate is deposited at the point intended for this purpose and provided with soldering paste. A similar positioning step is constituted by method step 16, in which the SMD resistor is likewise positioned and deposited at the point on the printed circuit board intended for this purpose and provided with soldering paste. In step 14, all soldering points are heated simultaneously by means of what is known as a reflow soldering process, are melted, and are therefore ultimately soldered. In the case of the contact sensor plate, this causes the soldering paste below the contact sensor plate, with which the lower face of the contact sensor plate is in contact, to melt. Since the heating process only lasts for a short time, both the tin alloy and the soldering paste cool quickly and assume a solid aggregate state. The contact sensor plate is thus soldered onto the printed circuit board. In step 17, the positioned SMD resistor is fastened by means as what is known as conductive adhesive bonding.

A possible design of the populating device 21 according to the invention can be seen schematically in FIG. 2. The populating device 21 comprises feeding means 22, severing means 23, positioning means 24 and fastening means 25. Feeding means 22 unwinds a roll, which contains a wound metal foil strip, stepwise and feeds an end piece of the foil strip to severing means 23. Severing means 23 are formed in the manner of a punching unit, which severs the end piece of the foil strip by means of punching. The severed end piece constitutes the contact sensor plate. Positioning means 24 consists of a movable positioning arm, which picks up the contact sensor plate by means of vacuum generation and positions and deposits it at the point intended therefore on a printed circuit board to be populated. Fastening means 25 are formed as a movable arm with a soldering tip, wherein the soldering tip locally heats the printed circuit board at the point of the contact sensor plate positioned thereon in order to effect a soldering process and to thus fasten the contact sensor plate on the printed circuit board.

In accordance with a further exemplary embodiment in FIG. 2, fastening means 25 are formed as a heating plate, which can heat and melt all soldering points simultaneously. This embodiment enables faster fastening or soldering of the contact sensor plates with comparatively low effort.

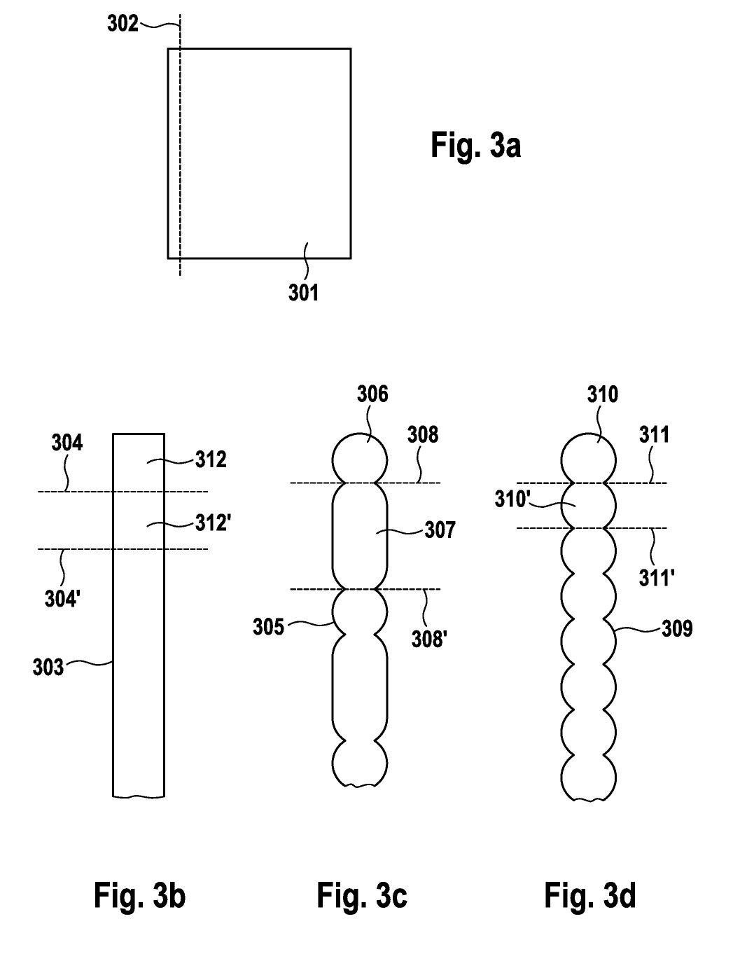

A metal foil 301 is illustrated by way of example in FIG. 3a. The metal foil 301 consists of thinly rolled sheet copper and is coated on the upper face with a silver alloy in order to improve the electrical conductivity. The lower face of the metal foil 301 is coated with a tin alloy, which is suitable for a good soldering bond.

A foil strip 303 (FIG. 3b) is then severed from the metal foil 301 along the dashed line 302. The severing is achieved by means of an automated sheet metal cutting process.

In accordance with a further exemplary embodiment in FIG. 3, the metal foil 301 is not coated with a tin alloy, but the foil strip 303 is coated galvanically once severed from the metal foil 301.

The foil strip 303 is then wound onto a roll and is unwound again stepwise during the feeding step of the method according to the invention. During the severing step of the method according to the invention, which is performed as a punching step, contact sensor plates 312 and 312′ are severed from the foil strip 33 along lines 304 and 304′ by means of punching. Due to the geometry of the foil strip 303 and due to the simple severing step, produced contact sensor plates 312 and 312′ are rectangular. The width of contact sensor plates 312 and 312′ is predefined by the width of the foil strip 303. The length of contact sensor plates 312 and 312′ is by contrast defined by the set step width of the feeding step and can be predefined as required.

FIG. 3c constitutes a further exemplary possibility for forming a foil strip 305. The foil strip 305 is provided with material recesses, which form the different geometries of contact sensor plates 306 and 307. The material recesses have already been introduced into the foil 301 by means of a punching method before the foil strip 305 is severed therefrom. The material recesses are also used during the feeding step to predefine a step width. By means of a suitable device, the recesses are identified and prevent a further feed if a severing step has not been performed. Contact sensor plates 306 and 307 are severed from the foil strip 305 along dashed lines 308 and 308′. As can be seen, two different geometries for the produced contact sensor plates are thus provided alternately, specifically a substantially disk-shaped geometry and an approximately oval geometry. The sequence of the geometries is adapted here to the requirements for population of the printed circuit board to be populated.

A further possibility for forming a foil strip 309 can be seen in FIG. 3d. Contact sensor plates 310 and 310′ to be produced are substantially disk-shaped by way of example. Other geometries of contact sensor plates 310 and 310′ are not provided in this case. The material recesses on the foil strip 309 are used to predefine a step width during the feeding step. Severing occurs along dashed lines 311 and 311′.

While the above description constitutes the preferred embodiment of the present invention, it will be appreciated that the invention is susceptible to modification, variation, and change without departing from the proper scope and fair meaning of the accompanying claims.

1. A method for producing an electric contact sensor plate and for populating an electric or electronic module with the contact sensor plate in an automated manner, the method comprising:
feeding an end piece of a metal foil strip (303, 305, 309) in a feeding step;
after feeding the end piece in the feeding step, severing the foil strip in a severing step and producing the contact sensor plate therefrom;
after producing the contact sensor plate in the severing step, positioning the contact sensor plate on the electric or electronic module in a positioning step; and
fastening the contact sensor plate on the electric or electronic module in a fastening step.

2. The method as claimed in claim 1, further comprising feeding the foil strip with a predefined step width.

3. The method as claimed in claim 1, further comprising providing the foil strip in a stored configuration wound into a roll or wound onto a roll and unwinding the roll in the feeding step.

4. The method as claimed in claim 1, further comprising severing the metal foil strip from a metal foil, wherein at least a first side of the foil is coated with a noble-metal coating.

5. The method as claimed in claim 4, further comprising providing the foil with shaped recesses, which form a geometry of the foil strip.

6. The method as claimed in claim 3, wherein the noble-metal coating consists of gold or silver or nickel or copper or of an alloy containing at least one of these metals.

7. The method as claimed in claim 4, wherein a second side of the foil is coated additionally or alternatively with a coating formed of solder.

8. The method as claimed in claim 1, wherein a width of the contact sensor plate defined by a width of the foil strip, and a length of the contact sensor plate is defined in the severing step.

9. The method as claimed in claim 1 further comprising producing the contact sensor plate substantially in a disk-shaped manner.

10. The method as claimed in claim 1, further comprising providing the electric or electronic module as a printed circuit board of an electronic control unit of a vehicle braking system.

11. A populating device for producing an electric contact sensor plate and for populating an electric or electronic module with the contact sensor plate in an automated manner, the device comprising:
feeding means;
positioning means;
fastening means; and
severing means,
wherein the feeding means feeds an end piece of a metal foil strip to the severing means for severing,
wherein the severing means severs the contact sensor plate from the foil strip,
wherein the positioning means positions the contact sensor plate on the electric or electronic module, and
wherein the fastening means fastens the contact sensor plate on the electric or electronic module.

12. The populating device as claimed in claim 11, wherein the populating device is formed as an SMD populating device and populates the electric or electronic module with SMD elements.

13. The populating device as claimed in claim 11, wherein the feeding means feeds the end piece of the foil strip by means of unwinding from a roll, and the positioning means picks up the contact sensor plate by means of suction and positions it on the electric or electronic module by means of a coordinated movement and deposits it by terminating the suction, and the fastening means solders the contact sensor plate onto the electric or electronic module by means of heating or adhesively bonds the contact sensor plate onto the electric or electronic module by means of conductive adhesive bonding.

14. The populating device as claimed in claim 11, wherein the severing means severs the contact sensor plate from the foil strip by means of cutting or punching.

15. The populating device as claimed in claim 11, wherein the populating device additionally populates the electric or electronic module with further elements.

16. A contact sensor plate which consists of gold or silver or nickel or copper or of an alloy containing at least one of these metals and in particular is produced by means of a populating device as claimed in claim 11 wherein the contact sensor plate is substantially two-dimensional and an extension in a third dimension is no greater than 3 mm.

17. The contact sensor plate of claim 16, wherein the contact sensor plate connects at least two electric contact points.

18. The method as claimed in claim 4, wherein the foil is provided with shaped recesses, which form a geometry of the contact sensor plate.

19. The method as claimed in claim 4, wherein the foil is provided with shaped recesses, which form a geometry of the step width of the feeding step.
